(19) United States
(12) Patent Application Publication
(10) Pub. No.: US 2009/0126967 A1
(43) Pub. Date: May 21, 2009

(54) THERMAL PACKAGING OF TRANSMISSION CONTROLLER USING CARBON COMPOSITE PRINTED CIRCUIT BOARD MATERIAL

(75) Inventor: Charles A. Spellman, Madison, AL (US)

Correspondence Address: CARLSON, GASKEY & OLDS, P.C., 400 WEST MAPLE ROAD, SUITE 350, BIRMINGHAM, MI, 48009, US

(73) Assignee: CONTINENTAL AUTOMOTIVE SYSTEMS US, INC., Auburn Hills, MI (US)

(21) Appl. No.: 12/272,116

(22) Filed: Nov. 17, 2008

Related U.S. Application Data
(60) Provisional application No. 61/003,472, filed on Nov. 16, 2007.

(51) Int. Cl. H05K 5/06; H05K 1/02; H05K 3/28; B29C 45/14

(52) U.S. Cl. 174/50.5; 174/527; 264/328.1

(57) ABSTRACT

A transmission controller includes a printed circuit board that mechanically supports and electrically connects circuitry of the transmission controller to a vehicle bus. The printed circuit board includes a lower layer of carbon composite and an upper layer of high temperature substrate. A flex circuit is laminated on the printed circuit board to provide an interconnect between the circuitry of the transmission controller and the vehicle bus. The circuitry is encased within a cover. The cover can formed by an overmolding process that encapsulates the circuitry on the upper layer of high temperature substrate or by lamination. The transmission controller can then be attached at a desired location within or on an outer surface of a transmission.

### REFERENCE TO RELATED APPLICATIONS

This application claims priority to U.S. Provisional Patent Application No. 61/003,472 filed on Nov. 16, 2007.

### BACKGROUND OF THE INVENTION

The present invention relates generally to a thermal packaging of a transmission controller utilizing a carbon composite printed circuit board material.

A printed circuit board (PCB) includes a high temperature substrate (such as low temperature co-fired ceramic or thick film ceramic) attached to an aluminum base plate, for example by gluing. A cover is then attached to the high temperature substrate by welding or gluing to form a module. The resulting module is then attached at a desired location within or on an outer surface of a transmission.

A drawback to employing an aluminum base plate is that it must be constructed to high manufacturing requirements in terms of flatness and surface defects to ensure adequate sealing to the high temperature substrate from environmental factors.

Hence, there is a need in the art for a transmission controller that utilizes a carbon composite printed circuit board material.

### SUMMARY OF INVENTION

A transmission controller includes a printed circuit board that mechanically supports and electrically connects circuitry of the transmission controller to a vehicle bus. The printed circuit board includes a lower layer of carbon composite and an upper layer of high temperature substrate that are laminated together. Copper etchings can be located on both sides of the high temperature substrate.

Circuitry is attached to the upper layer of high temperature substrate, and a flex circuit is laminated on the printed circuit board. The circuitry is in contact with the flex circuit to provide an interconnect between the circuitry of the transmission controller and the vehicle bus.

The circuitry is then encased within a cover. An overmolding process can be employed to form the cover on the upper layer of high temperature substrate that encapsulates the circuitry. In another example, a cover is laminated over the circuitry.

The transmission controller can then be attached at a desired location within or on an outer surface of a transmission to provide an interconnect between the circuitry of the transmission controller and the vehicle bus.

These and other features of the present invention will be best understood from the following specification and drawings.

### BRIEF DESCRIPTION OF THE FIGURES

The various features and advantages of the invention will become apparent to those skilled in the art from the following detailed description of the currently preferred embodiment. The drawings that accompany the detailed description can be briefly described as follows:

FIG. 1 schematically illustrates a transmission controller attached to a transmission; and

FIG. 2 illustrates a forming tool that is used to form an overmold cover that encases the circuitry of the transmission controller.

### DETAILED DESCRIPTION OF THE DRAWINGS

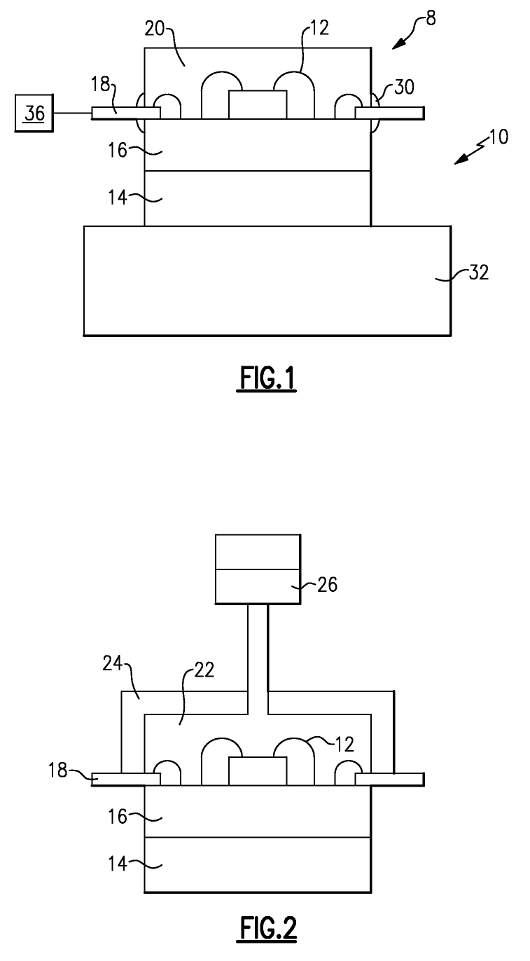

FIG. 1 shows a transmission controller 8 including a printed circuit board 10 (PCB) that mechanically supports and electrically connects circuitry 12 of the transmission controller 8 to a vehicle bus 36. The printed circuit board 10 includes a lower layer of carbon composite 14 and an upper layer of high temperature substrate 16 (for example, low temperature co-fired ceramic, thick film ceramic, or FR4, which is woven glass and epoxy). The lower layer of carbon composite 14 and the upper layer of high temperature substrate 16 are laminated together. That is, the lower layer of carbon composite 14 and the upper layer of high temperature substrate 16 are located between layers of dielectric and sealed together using heat and/or pressure. In one example, the printed circuit board 10 is sold under the registered trademark Stablcor® by ThermalWorks, Inc. of Huntington Beach, Calif.

The lower layer of carbon composite 14 has a higher thermal conductivity than aluminum and substrate materials. The inclusion of the lower layer of carbon composite 14 provides high levels of thermal dissipation. For example, Stablcor® PCB has a thermal conductivity of approximately 10 W/mK. While the thermal conductivity of the printed circuit board 10 is lower than aluminum, no interface materials (such as internal material, thermal paste, epoxy, etc.) are required to secure the lower layer of carbon composite 14 and the upper layer of high temperature substrate 16 together as these layers 14 and 16 are laminated together. Therefore, thermal vias within the upper layer of high temperature substrate 16 can terminate on the lower layer of carbon composite 14 without further interface materials, providing efficient transmission of heat.

Copper etchings can be located on both sides of the upper layer of high temperature substrate 16. The copper etchings are conducting layers, and the upper layer of high temperature substrate 16 is an insulting layer.

In one example, the lower layer of carbon composite 14 and the upper layer of high temperature substrate 16 are laminated together at the supplier via a normal printed circuit board build up process and delivered to the plant with the lower layer of carbon composite 14 as the bottom layer. The laminated lower layer of carbon composite 14 and the upper layer of high temperature substrate 16 can be cut into the desired shape and size at the supplier or at the plant. The circuitry 12 and the remaining components of the transmission controller 8 can then be attached. In another example, the circuitry 12 and the remaining components of the transmission controller 8 are attached to the upper layer of the high temperature substrate 16, and then the lower layer of carbon composite 14 is laminated to the upper layer of high temperature substrate 16 at the end of the manufacturing processing.

As no interface materials or adhesive are needed to attach the lower layer of carbon composite 14 to the upper layer of high temperature substrate 16, the resulting printed circuit board 10 can be manufactured with a reduced processing step and at a lower cost.

The circuitry 12 is attached to the upper layer of high temperature substrate 16. A flex circuit 18 is laminated on the printed circuit board 10, and the circuitry 12 is in contact with the flex circuit 18 prior to encasing the circuitry 12 within a cover 20 (as described below). The flex circuit 18 provides an interconnect between the circuitry 12 of the transmission controller 8 and the vehicle bus 36.

The circuitry 12 is then encased within the cover 20. In one example, the cover 20 is formed by employing an overmolding process that encapsulates the circuitry 12 on the upper layer of high temperature substrate 16. In one example shown in FIG. 2, an upper portion of the printed circuit board 10 with the associated circuitry 12 is placed in a cavity 22 of a tool 24. A plastic material 26 is injected into the cavity 22 and flows over the circuitry 12 and onto the upper layer of high temperature substrate 16. Returning to FIG. 1, the plastic material 26 forms the cover 20 that hardens on the upper layer of high temperature substrate 16 and forms a mechanical bond with the upper layer of high temperature substrate 16. In another example, a cover 20 is laminated over the circuitry 12 on the upper layer of high temperature substrate 16 to encase the circuitry.

Once the cover 20 is attached to the upper layer of high temperature substrate 16, a seal 30 can be added around a perimeter of the cover 20 to prevent moisture from contacting the circuitry 12.

The transmission controller 8 can then be attached at a desired location within or on an outer surface of a transmission 32. In one example, the transmission controller 8 is bolted within or on the outer surface of the transmission 32 to provide an interconnect between the circuitry 12 of the transmission controller 8 and the vehicle bus 36.

The foregoing description is only exemplary of the principles of the invention. Many modifications and variations of the present invention are possible in light of the above teachings. The preferred embodiments of this invention have been disclosed, however, so that one of ordinary skill in the art would recognize that certain modifications would come within the scope of this invention. It is, therefore, to be understood that within the scope of the appended claims, the invention may be practiced otherwise than as specifically described. For that reason the following claims should be studied to determine the true scope and content of this invention.

What is claimed is:

1 A transmission controller comprising:
a printed circuit board including a bottom layer of carbon composite, a layer of high temperature substrate, and circuitry attached to the layer of high temperature substrate; and
an overmolded cover to encase the circuitry.

2. The transmission controller as recited in claim 1 wherein the layer of high temperature substrate is one of low temperature co-fired ceramic, thick film ceramic and FR4.

3. The transmission controller as recited in claim 1 wherein the printed circuit board is Stablcor.

4. The transmission controller as recited in claim 1 wherein the layer of high temperature substrate and the layer of carbon composite are laminated together.

5. The transmission controller as recited in claim 1 wherein copper etchings are located on a first side and an opposing second side of the layer of high temperature substrate.

6. The transmission controller as recited in claim 1 wherein a flex circuit is located on the printed circuit board, and the circuitry is in contact with the flex circuit to provide an interconnect between the circuitry and a bus.

7. The transmission controller as recited in claim 1 wherein the overmolded cover is laminated over the circuitry.

8. The transmission controller as recited in claim 1 wherein a seal surrounds a perimeter of the cover to prevent moisture from contacting the circuitry.

9. A transmission comprising:
a transmission controller including a printed circuit board having a bottom layer of carbon composite, a layer of high temperature substrate, and circuitry attached to the layer of high temperature substrate to provide an interconnect between the circuitry and a vehicle bus;
an overmolded cover to encase the circuitry; and
a transmission, wherein the transmission controller is attached to an outer surface of the transmission.

10. The transmission as recited in claim 9 wherein the layer of high temperature substrate is one of low temperature co-fired ceramic, thick film ceramic or FR4.

11. The transmission as recited in claim 9 wherein the printed circuit board is Stablcor.

12. The transmission as recited in claim 9 wherein the layer of high temperature substrate and the layer of carbon composite are laminated together.

13. The transmission as recited in claim 9 wherein copper etchings are located on a first side and an opposing second side of the layer of high temperature substrate.

14. The transmission as recited in claim 9 wherein a flex circuit is located on the printed circuit board, and the circuitry is in contact with the flex circuit to provide an interconnect between the circuitry and a bus.

15. The transmission controller as recited in claim 9 wherein the overmolded cover is laminated over the circuitry.

16. The transmission as recited in claim 9 wherein a seal surrounds a perimeter of the cover to prevent moisture from contacting the circuitry.

17. A method of forming a transmission controller, the method comprising the steps of:
providing a printed circuit board including a layer of carbon composite, a layer of high temperature substrate, and circuitry attached to the layer of high temperature substrate; and
positioning the circuitry of the printed circuit board in a cavity of a tool;
injecting a material into the cavity; and
hardening the material to form an overmolded cover over the circuitry to encase the circuitry.
